(19) United States
(12) Patent Application Publication
(10) Pub. No.: US 2023/0113513 A1
(43) Pub. Date: Apr. 13, 2023

(54) SEMICONDUCTOR DEVICE AND METHOD OF MANUFACTURING THE SAME

(71) Applicant: RENESAS ELECTRONICS CORPORATION, Tokyo (JP)

(72) Inventors: Katsunori TSUNETSUGU, Tokyo (JP); Yasutaka NAKASHIBA, Tokyo (JP)

(21) Appl. No.: 17/886,024

(22) Filed: Aug. 11, 2022

(30) Foreign Application Priority Data
Oct. 8, 2021 (JP) 2021-166237

(51) Int. Cl. H01L 49/02; H01L 23/522; H01L 23/495; H01L 23/528

(52) U.S. Cl. CPC H01L 28/10; H01L 23/5227; H01L 23/49503; H01L 23/49541; H01L 23/49575; H01L 23/5283

(57) ABSTRACT

A multilayer wiring structure in which a plurality of conductive films and a plurality of interlayer dielectric films are laminated is formed so as to cover a main surface of a first semiconductor chip. The conductive films include conductive films to which a low voltage is applied and conductive films to which a high voltage is applied. The conductive films to which the low voltage is applied are located below the conductive films to which the high voltage is applied and closer to the main surface of a semiconductor substrate. The conductive films are arranged as conductive films of at least one layer between a first inductor to which the low voltage is applied and a second inductor to which the high voltage is applied.

### CROSS-REFERENCE TO RELATED APPLICATIONS

The disclosure of Japanese Patent Application No. 2021-166237 filed on Oct. 8, 2021, including the specification, drawings and abstract is incorporated herein by reference in its entirety.

### BACKGROUND

The present invention relates to a semiconductor device and method of manufacturing the same, for example, the present invention can be suitably applied to a semiconductor device having a micro-isolator.

In recent years, for environmental protection, in the field of automobiles, the conversion from gasoline engines to motors has been attempted as a power source. The speed of the motor is controlled by the semiconductor device of the power system equipped with power semiconductor elements for electric power. The power semiconductor device is controlled by a semiconductor device with a microcomputer.

The semiconductor device with power semiconductor devices for electric power is capable of handling voltages ranging from several hundred V to one thousand several hundred V. On the other hand, a semiconductor device with a microcomputer is driven by a few volts. To control a semiconductor device equipped with a power semiconductor element for electric power by a microcomputer, a micro-isolator (digital isolator) is applied to transmit and receive electric signals between a circuit including a power semiconductor element and a circuit including a microcomputer.

In a micro-isolator, transmission of electric signals will be performed between an inductor (one inductor) electrically connected to a circuit including a microcomputer and an inductor (the other inductor) electrically connected to a circuit including a power semiconductor element by using electromagnetic induction.

There are disclosed techniques listed below.

### [Patent Document 1] Japanese Unexamined Patent Application Publication No. 2011-082212

### [Patent Document 2] WO 2015/114758

As a structure for transmitting this electric signal, there is a structure in which one inductor is arranged on a semiconductor substrate, and the other inductor is arranged by interposing an interlayer dielectric film on the one inductor. Patent Document 1 and Patent Document 2 disclose a semiconductor device with such a structure.

### SUMMARY

In the multilayer wiring structure in the semiconductor device described above, a plurality of conductive films constituting a circuit including a microcomputer is laminated. The plurality of conductive films includes a conductive film formed in the same layer as the other inductor. Therefore, between the conductive film to which a low voltage is applied and the conductive film including the other inductor to which a high voltage is applied, a current flows along the dielectric interface, it is assumed to be electrically short-circuited.

Other objects and novel features will become apparent from the description of this specification and the accompanying drawings.

A semiconductor device according to one embodiment is a semiconductor device including a first semiconductor chip in which a first semiconductor circuit, a first inductor and a second inductor are formed. The first semiconductor chip has a semiconductor substrate having a main surface and a multilayer wiring structure. The multilayer wiring structure is formed so as to cover the main surface of the semiconductor substrate, a plurality of conductive films and a plurality of interlayer dielectric films are laminated. The plurality of conductive films in the multilayer wiring structure includes a first conductive film group and a second conductive film group. The first conductive film group includes the first inductor to which first voltage is applied and constitutes the first semiconductor circuit. The second conductive film group includes the second inductor to which second voltage different from the first voltage is applied. The first conductive film group is arranged in a layer close to the main surface and below a layer in which the second conductive film group is arranged. When i and j are defined as natural numbers representing an order of layers laminated sequentially from the main surface of the semiconductor substrate in the plurality of conductive films, the first inductor is arranged in an i-th layer, and the second inductor is arranged in a j-th layer. At least one layer of the plurality of conductive films is arranged between the i-th layer and the j-th layer.

A method of manufacturing a semiconductor device according to another embodiment is a method of manufacturing a semiconductor device including manufacturing process of a first semiconductor chip including a first inductor, a second inductor and a semiconductor circuit having a semiconductor element. The manufacturing process of the first semiconductor chip includes the following steps. A semiconductor substrate having a main surface is prepared. A semiconductor element is formed in the main surface of the semiconductor substrate. A multilayer wiring structure is formed by laminating a plurality of conductive films constituting the semiconductor circuit and electrically connected to the semiconductor element, and a plurality of interlayer dielectric films so as to cover the main surface of the semiconductor substrate. The step of forming the multilayer wiring structure includes the following steps. A first conductive film group including a first inductor to which first voltage is applied and constituting the semiconductor circuit. An interlayer dielectric film is formed so as to cover the first conductive film group. A second conductive film group including a second inductor to which second voltage different from the first voltage is applied so as to cover the interlayer dielectric film. When i and j are defined as natural numbers representing an order of layers laminated sequentially from the main surface of the semiconductor substrate in the plurality of conductive films, the forming the first conductive film group includes forming the first inductor in an i-th layer, and the forming the second conductive film group includes forming the second inductor in a j-th layer. The forming the multilayer wiring structure includes forming at least one layer of the plurality of conductive films between the i-th layer and the j-th layer.

According to a semiconductor device according to one embodiment, it is possible to suppress the current flows along the dielectric interface and electrically short-circuiting.

According to a method of manufacturing a semiconductor device according to another embodiment, it is possible to manufacture a semiconductor device that prevents a current from flowing along the dielectric interface and electrically short-circuiting.

### BRIEF DESCRIPTION OF THE DRAWINGS

FIG. 1 is a circuit diagram showing one example of a circuit of a semiconductor device according to the respective embodiments.

FIG. 2 is a plan view showing one example of the semiconductor device according to the first embodiment.

FIG. 3 is a cross-sectional view showing the structure of the first semiconductor chip in the cross-sectional line III-III shown in FIG. 2.

FIG. 4 is a cross-sectional view showing one step of a method of manufacturing the first semiconductor chip in the semiconductor device in the embodiment.

FIG. 5 is a cross-sectional view showing a process performed after the process shown in FIG. 4 in the embodiment.

FIG. 6 is a cross-sectional view showing a step performed after the process shown in FIG. 5 in the embodiment.

FIG. 7 is a cross-sectional view showing a step performed after the process shown in FIG. 6 in the embodiment.

FIG. 8 is a cross-sectional view showing a step performed after the process shown in FIG. 7 in the embodiment.

FIG. 9 is a cross-sectional view showing a step performed after the process shown in FIG. 8 in the embodiment.

FIG. 10 is a cross-sectional view showing a step performed after the process shown in FIG. 9 in the embodiment.

FIG. 11 is a cross-sectional view showing a structure of the semiconductor device according to a comparative example.

FIG. 12 is a cross-sectional view of the semiconductor substrate for explaining a problem with the semiconductor device according to the comparative example.

FIG. 13 is a plan view showing a state in which the semiconductor substrate is transferred by the transfer arm for explaining a problem with the semiconductor device according to the comparative example.

FIG. 14 is a cross-sectional view showing a state in which the semiconductor substrate is transferred by the transfer arm for explaining a problem with the semiconductor device according to the comparative example.

FIG. 15 is a cross-sectional view showing a state in which the semiconductor substrate is mounted on a wafer stage for explaining a problem with the semiconductor device according to the comparative example.

FIG. 16 is a cross-sectional view of the semiconductor substrate for explaining the effect of the semiconductor device in the embodiment.

FIG. 17 is a cross-sectional view showing a state in which the semiconductor substrate is transferred by the transfer arm for explaining the effect of the semiconductor device in the embodiment.

FIG. 18 is a cross-sectional view showing a state in which the semiconductor substrate is mounted on a wafer stage for explaining the effect of the semiconductor device in the embodiment.

FIG. 19 is a cross-sectional view showing the structure of the first semiconductor chip in the semiconductor device according to the second embodiment.

FIG. 20 is a partial plan view showing the structure of the first semiconductor chip in the semiconductor device according to third embodiment.

FIG. 21 is a cross-sectional view showing the structure of the first semiconductor chip in the cross-sectional line XXI-XXI shown in FIG. 20 in the embodiment.

FIG. 22 is a cross-sectional view showing one step of a method of manufacturing the first semiconductor chip in the semiconductor device according to the embodiment.

FIG. 23 is a cross-sectional view showing a step performed after the process shown in FIG. 22 in the embodiment.

FIG. 24 is a cross-sectional view showing a step performed after the process shown in FIG. 23 in the embodiment.

FIG. 25 is a cross-sectional view showing a step performed after the process shown in FIG. 24 in the embodiment.

### DETAILED DESCRIPTION

First, one example of circuit of a semiconductor device equipped with a micro-isolator according to the respective embodiments will be described.

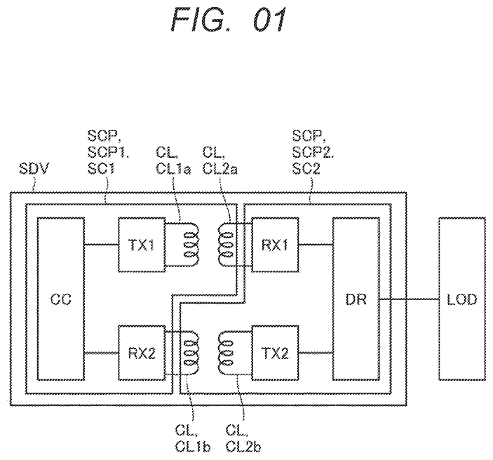

As shown in FIG. 1, a semiconductor device SDV, as a semiconductor chip SCP, includes a first semiconductor chip SCP1 and a second semiconductor chip SCP2. In the first semiconductor chip SCP1, a first semiconductor circuit SC1 including a semiconductor element or the like for controlling the driving of the load LOD is formed. In the second semiconductor chip SCP2, a second semiconductor circuit SC2 including a semiconductor element or the like for driving the load LOD such as a motor is formed.

The first semiconductor circuit SC1 includes a control circuit CC, a receiver circuit RX2 and a transmission circuit TX1. The receiver circuit RX2 and the transmission circuit TX1 are electrically connected to the control circuit CC. The first inductor CL1a is electrically connected to the transmission circuit TX1. The third inductor CL1b is electrically connected to the receiver circuit RX2. The first semiconductor circuit SC1 is operated (driven) in a few volts.

The second semiconductor circuit SC2 includes a drive circuit DR, a receiver circuit RX1 and a transmission circuit TX2. The drive circuit DR is electrically connected to the load LOD. The receiver circuit RX1 and the transmission circuit TX2 are electrically connected to the drive circuit DR. The second inductor CL2a is electrically connected to the receiver circuit RX1. The fourth inductor CL2b is electrically connected to the transmission circuit TX2. The second semiconductor circuit SC2 operates (drives) at about several hundred (V) to one thousand and several hundred (V).

The first inductor CL1a and the second inductor CL2a are arranged so as to face each other. The first inductor CL1a and the second inductor CL2a are magnetically coupled. The third inductor CL1b and the fourth inductor CL2b are arranged so as to face each other. The third inductor CL1b and the fourth inductor CL2b are magnetically coupled.

Signals are transmitted from the control circuit CC to the transmission circuit TX1. The signals transmitted to the transmission circuit TX1 flows through the first inductor CL1a as a current. By current flows through the first inductor CL1a as a coil, the induced current flows in the second inductor CL2a as a coil by electromagnetic induction. The induced current flowing through the second inductor CL2a is transmitted to the drive circuit DR through the receiver circuit RX1 as signals. Thus, the signals of the control circuit CC is transmitted to the drive circuit DR.

On the other hand, signals are transmitted from the drive circuit DR to the transmission circuit TX2. The signals transmitted to the transmission circuit TX2 flows through the fourth inductor CL2b as a current. By current flows through the fourth inductor CL2b as a coil, induced current flows in the third inductor CL1b as a coil by electromagnetic induction. The induced current flowing through the third inductor CL1b is transmitted to the control circuit CC through the receiver circuit RX2 as signals. Thus, the signals of the drive circuit DR is transmitted to the control circuit CC. By this series of operations, the driving of the load LOD is controlled. Hereinafter, the structure of the semiconductor device SDV will be described in detail.

### First Embodiment

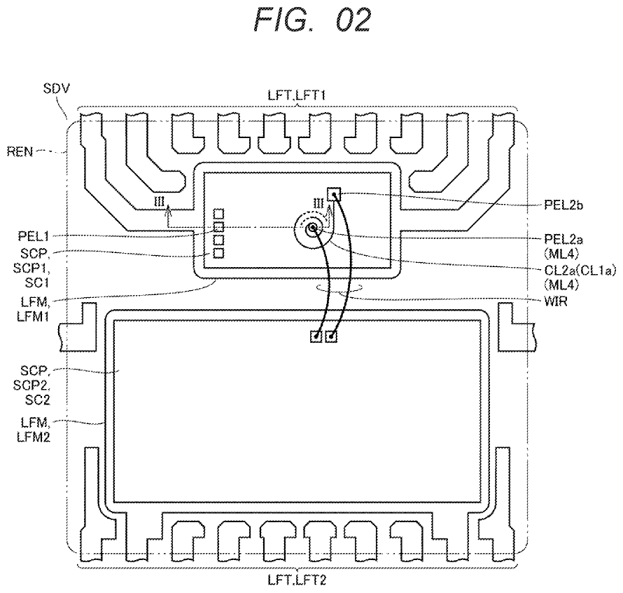

The semiconductor device SDV related to the first embodiment will be described. First, one example of the overall structure of the semiconductor device SDV is explained. As shown in FIG. 2, in the semiconductor device SDV, the semiconductor chip SCP is mounted on the lead frame LFM. The first semiconductor chip SCP1 is mounted on the lead frame LFM1. The second semiconductor chip SCP2 is mounted on the lead frame LFM2.

The first semiconductor chip SCP1 is electrically connected to the corresponding lead frame LFM1, for example, by wires (not shown). The second semiconductor chip SCP2 is electrically connected to the corresponding lead frame LFM2, for example, by wires (not shown).

The semiconductor chip SCP mounted on the lead frame LFM is sealed by a sealing resin REN. A lead terminal LFT protrudes from the sealing resin REN. A lead terminal LFT includes a lead terminal LFT1 and a lead terminal LFT2. The lead terminal LFT1 is connected to the lead frame LFM1. The lead terminal LFT2 is connected to the lead frame LFM2.

A first electrode pad PEL1 is formed in the first semiconductor chip SCP1. The first electrode pad PEL1 and the corresponding lead frame LFM1 are electrically connected by wires (not shown). Further, the first inductor CL1a and the second inductor CL2a are arranged in the first semiconductor chip SCP1. The first inductor CL1a is arranged below the second inductor CL2a so as to face the second inductor CL2a.

The second inductor CL2a is formed in a spiral shape. The first inductor CL1a is also formed in a spiral shape (not shown). One end of the second inductor CL2a is connected to a second electrode pad 2a. The other end of the second inductor CL2a is connected to a second electrode pad 2b. The second electrode pads 2a and 2b and the second semiconductor chip SCP2 are electrically connected by wires WIR. Incidentally, in order to stabilize the operation as the second inductor CL2a, the two second inductors CL2a may be arranged in parallel so that the winding directions are the same.

On the other hand, the fourth inductor CL2b (refer to FIG. 1) and the third inductor CL1b (refer to FIG. 1) are arranged in the second semiconductor chip SCP2 (both not shown). The fourth inductor CL2b is arranged below the third inductor CL1b so as to face the third inductor CL1b. The third inductor CL1b is electrically connected to the first semiconductor chip SCP1 by the wire (not shown).

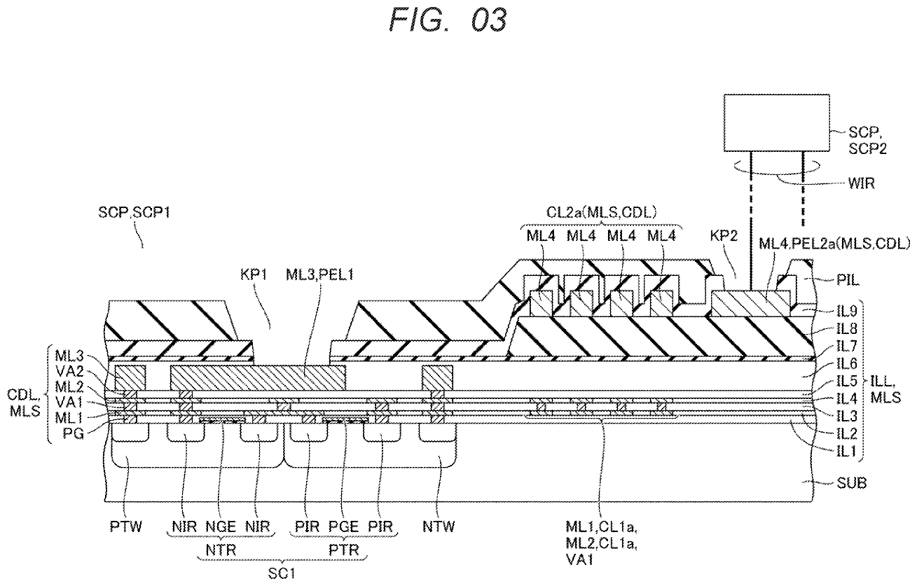

The first semiconductor chip SCP1 will be described in detail. As shown in FIG. 3, in the first semiconductor chip SCP1, n-channel transistor NTR and p-channel transistor PTR are formed in a predetermined region in the main surface of the semiconductor substrate SUB, for example. The n-channel transistor NTR and the p-channel transistor PTR constitute a part of the first semiconductor circuit SC1.

The n-channel transistor NTR is formed on the p-type well PTW. A pair of n-type impurity regions NIR as a source and a drain are formed in the p-type well PTW. On the surface of the portion of the p-type well PTW sandwiched by the pair of n-type impurity regions NIR, a gate electrode NGE is formed by interposing a gate dielectric film.

The p-channel transistor PTR is formed on the n-type well NTW. A pair of p-type impurity regions PIR as a source and a drain are formed in the n-type well NTW. On the surface of the portion of the n-type well NTW sandwiched by the pair of p-type impurity regions PIR, a gate electrode PGE is formed by interposing a gate dielectric film.

The multilayer wiring structure MLS is formed so as to cover the main surface of the semiconductor substrate SUB. In the multilayer wiring structure MLS, a plurality of conductive films CDL and a plurality of interlayer dielectric films ILL are laminated. A conductive film CDL as a wiring is electrically connected to the n-channel transistor NTR and the p-channel transistor PTR or the like. The conductive film CDL constitutes a part of the first semiconductor circuit SC1.

An interlayer dielectric film IL1 is formed over the main surface of the semiconductor substrate SUB so as to cover the n-channel transistor NTR and the p-channel transistor PTR. Contact plugs PG are formed so as to penetrate the interlayer dielectric film IL1. An interlayer dielectric film IL2 is formed so as to cover the interlayer dielectric film IL1. Conductive films ML1 are formed in trenches of the interlayer dielectric film IL2. The conductive films ML1 include wirings in the first layer and the first inductor CL1a in the first layer.

An interlayer dielectric film IL3 is formed so as to cover the interlayer dielectric film IL2. Vias VA1 are formed so as to penetrate the interlayer dielectric film IL3. An interlayer dielectric film IL4 is formed so as to cover the interlayer dielectric film IL3. Conductive films ML2 are formed in trenches of the interlayer dielectric film IL4. The conductive films ML2 include wirings of the second layer and the first inductor CL1a of the second layer. The first inductor CL1a of the second layer and the first inductor CL1a of the first layer is electrically connected by the vias VA1.

An interlayer dielectric film IL5 is formed so as to cover the interlayer dielectric film IL4. Vias VA2 are formed so as to penetrate the interlayer dielectric film IL5. Conductive films ML3 are formed on the surface of the interlayer dielectric film IL5. The conductive films ML3 include wirings of the third layer and a first electrode pad PEL1.

An interlayer dielectric film IL6 is formed so as to cover the conductive films ML3. An interlayer dielectric film IL7 is formed so as to cover the interlayer dielectric film IL6. An interlayer dielectric film IL8 is formed so as to cover the interlayer dielectric film IL7. The interlayer dielectric film IL8 is formed in a region where the second inductor CL2a and the second electrode pad PEL2a or the like are arranged. The interlayer dielectric film IL8 is not formed in a region where the second inductor CL2a or the like is not arranged.

A second inductor CL2a and a second electrode pad PEL2a are formed on the surface of the interlayer dielectric film IL8. An interlayer dielectric film IL9 is formed to cover the second inductor CL2a and the interlayer dielectric film IL7 or the like. A polyimide film PIL is formed so as to cover the interlayer dielectric film IL9. An opening KP1 exposing the surface of the first electrode pad PEL1 is formed. An opening KP2 exposing the surface of the second electrode pad PEL2a is formed. The second electrode pad PEL2a is electrically connected to the second semiconductor chip SCP2 by a wire WIR.

In the first semiconductor chip SCP1 of the semiconductor device SDV described above, the first inductor CL1a is formed by the conductive film ML1 and the conductive film ML2 (i-th layer). The second inductor CL2a is formed by the conductive film ML4 (j-th layer). That is, between the first inductor CL1a to which low voltage is applied and the second inductor CL2a to which high voltage is applied, the conductive film ML3 is arranged as a conductive film CDL of at least one layer. In other words, the first inductor CL1a to which low voltage is applied is formed two layers (layers of the conductive film CDL) below than the second inductor CL2a to which high voltage is applied.

The plurality of conductive films CDL in the multilayer wiring structure MLS includes conductive films CDL (first conductive film group) constituting the first semiconductor circuit including the first electrode pad PEL1 and the first inductor CL1a, and conductive films CDL (second conductive film group) constituting the second inductor CL2a and the second electrode pad PEL2a and the like.

That is, the conductive films CDL include conductive films ML1, ML2, ML3 (the first conductive film group) to which low voltage is applied and conductive films ML4 (the second conductive film group) to which high voltage is applied. The conductive films ML1, ML2, ML3 to which the low voltage is applied are located below the conductive films ML4 to which the high voltage is applied and closer to the main surface (layers) of the semiconductor substrate SUB.

Next, one example of a method of manufacturing the first semiconductor chip SCP1 in the semiconductor device SDV described above is explained.

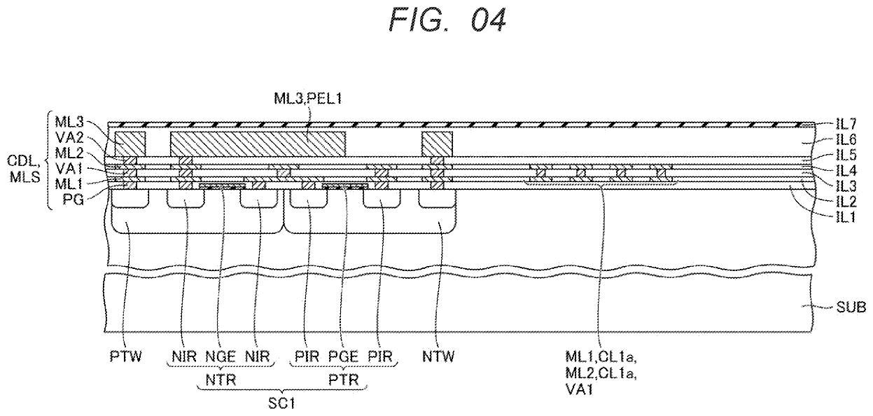

First, as shown in FIG. 4, the semiconductor substrate SUB having the main surface is prepared. Next, a photolithography process is performed on the semiconductor substrate SUB and p-type impurities and n-type impurities are implanted, respectively. Thus, the p-type well PTW and the n-type well NTW are formed. Next, by performing photolithography process to the semiconductor substrate SUB and implanting n-type impurities, n-type impurity regions NIR are formed in the p-type well PTW. The p-type impurity regions PIR are formed in the n-type well NTW by performing photolithography process to the semiconductor substrate SUB and implanting the p-type impurities.

Next, the gate electrode NGE is formed on the p-type well PTW by interposing the gate dielectric film. The gate electrode PGE is formed on the n-type well NTW by interposing the gate dielectric film. Next, the interlayer dielectric film IL1 is formed so as to cover the gate electrode NGE and the gate electrode PGE. Next, the contact plugs PG penetrating through the interlayer dielectric film IL1 are formed. Next, the interlayer dielectric film IL2 is formed so as to cover the interlayer dielectric film IL1.

Next, trenches are formed in the interlayer dielectric film IL2, and conductive films ML1 are formed in the trenches. At this time, the first inductor CL1a (conductive film ML1) is formed at the same time. Next, the interlayer dielectric film IL3 is formed so as to cover the interlayer dielectric film IL2. Next, the vias VA1 are formed so as to penetrate the interlayer dielectric film IL3. Next, the interlayer dielectric film IL4 is formed so as to cover the interlayer dielectric film IL3.

Next, trenches are formed in the interlayer dielectric film IL4, and the conductive films ML2 are formed in the trenches. The first inductor CL1a (conductive film ML2) is formed at the same time. The first inductor CL1a (conductive film ML2) and the first inductor CL1a (conductive film ML1) is electrically connected by the vias VA1. Next, the interlayer dielectric film IL5 is formed so as to cover the interlayer dielectric film IL4.

Next, the vias VA2 are formed so as to penetrate the interlayer dielectric film IL5. Next, the conductive films ML3 are patterned on the surface of the interlayer dielectric film IL5. At this time, the first electrode pad PEL1 (conductive film ML3) is formed at the same time. As a result, the conductive films CDL serving as the first conductive film group are formed. Next, the interlayer dielectric film IL6 is formed so as to cover the conductive films ML3. Next, the interlayer dielectric film IL7 is formed so as to cover the interlayer dielectric film IL6.

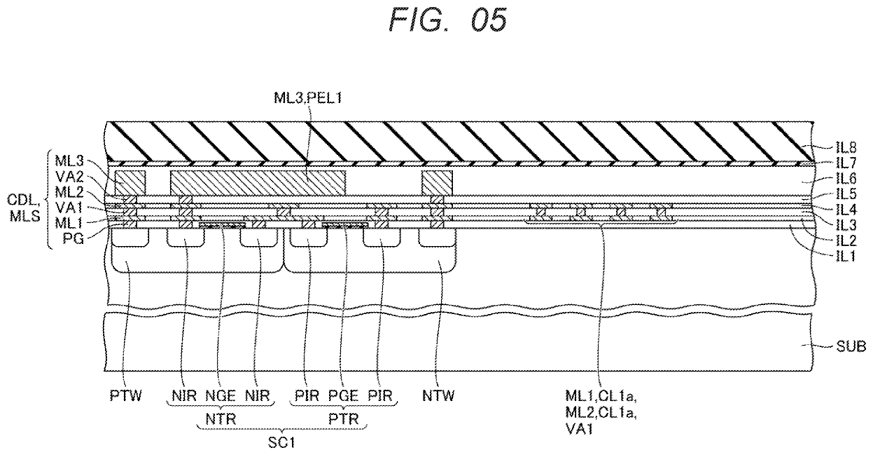

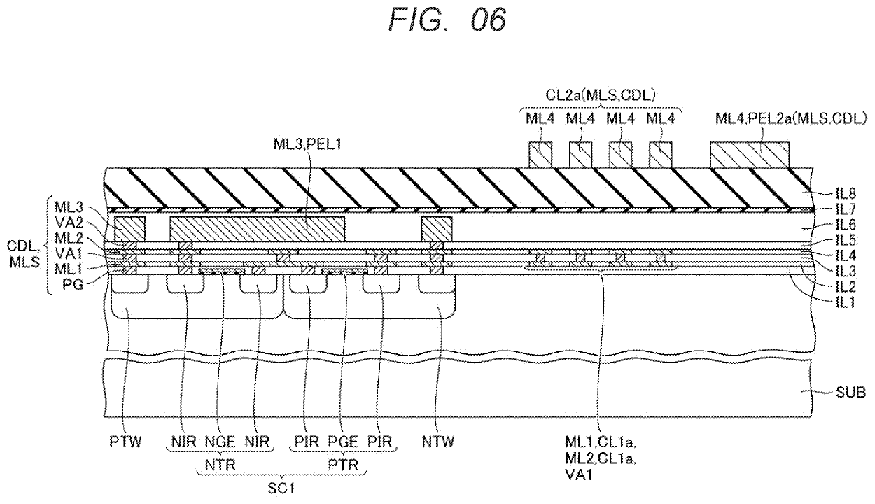

Next, as shown in FIG. 5, the interlayer dielectric film IL8 is formed so as to cover the interlayer dielectric film IL7. The thickness of the interlayer dielectric film IL8 is thicker than the film thickness of the other interlayer dielectric film IL7 or the like, for example, is about 4 μm. By increasing the film thickness of the interlayer dielectric film IL8, the breakdown voltage between the first inductor CL1a and the second inductor CL2a formed in the following step (see FIG. 6, etc.) is ensured.

Next, as shown in FIG. 6, the conductive films ML4 are patterned on the surface of the interlayer dielectric film IL8. At this time, the second inductor CL2a and the second electrode pad PEL2a or the like are formed at the same time. Thus, the conductive films CDL serving as the second conductive film group are formed. Incidentally, by patterning the conductive films ML4 prior to partial removal of the interlayer dielectric film IL8 performed in the following step, it is possible to suppress the defocus in the photolithography process. Further, by the conductive films CDL serving as the first conductive film group are formed on the side (layer) closer to the main surface of the semiconductor substrate SUB than the conductive films CDL serving as the second conductive film group, it is possible to prevent an electric short-circuiting along the dielectric interface.

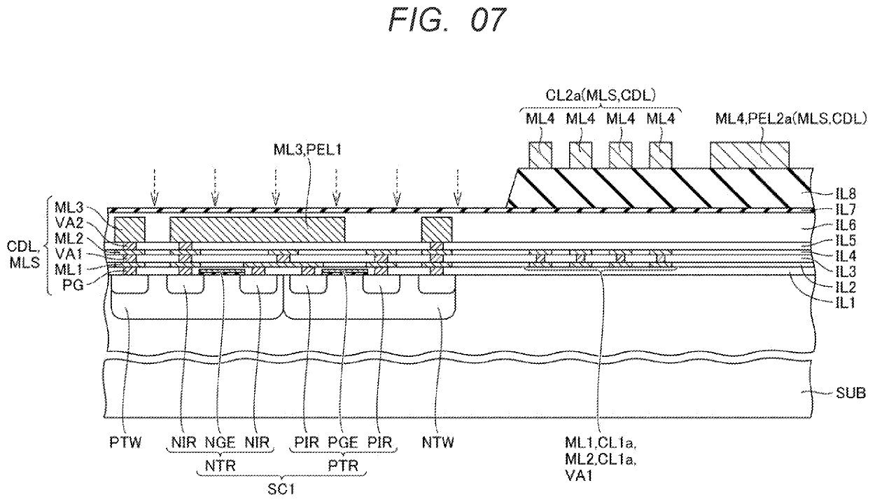

Next, the interlayer dielectric film IL8 having a relatively large thickness is partially removed. As shown in FIG. 7, by performing a photolithography process and etching process on the interlayer dielectric film IL8, a portion of the interlayer dielectric film CL2a located in a region where the second inductor CL2a and the second electrode pad PEL2a or the like are arranged is left, and a portion of the interlayer dielectric film IL8 located in the other region is removed.

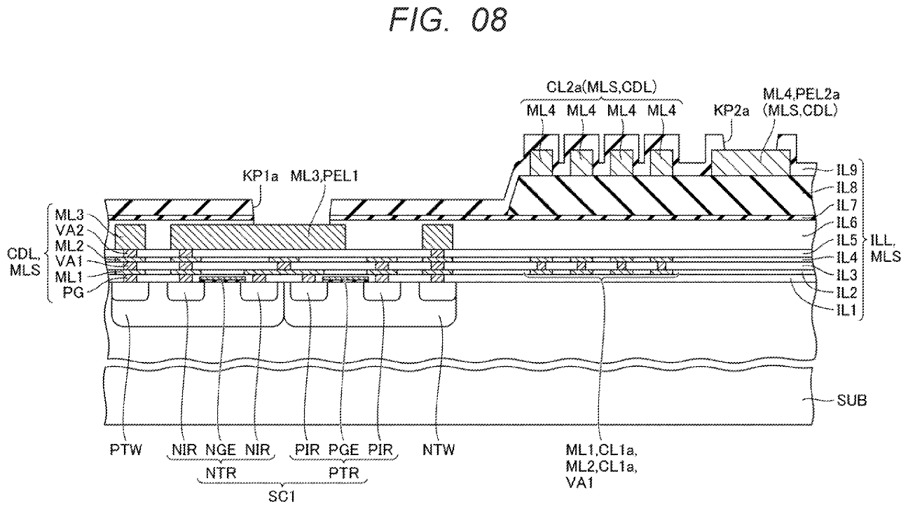

Next, as shown in FIG. 8, the interlayer dielectric film IL9 is formed so as to cover the second inductor CL2a and the interlayer dielectric film IL7 or the like. Next, by performing a photolithography process and etching process on the interlayer dielectric film IL9, an opening KP1a exposing the first electrode pad PEL1 is formed. An opening KP2a exposing the second electrode pad PEL2a is formed.

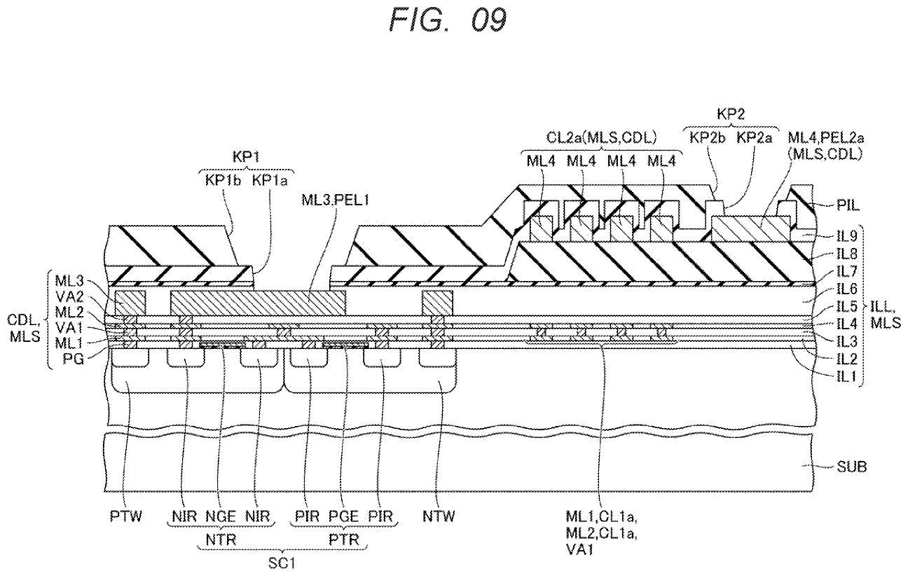

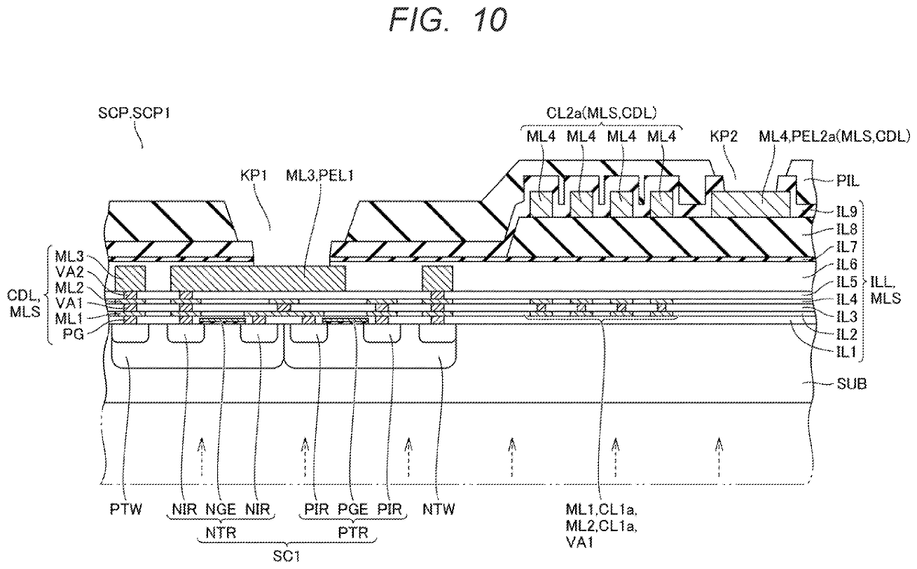

Next, as shown in FIG. 9, the polyimide film PIL is formed so as to cover the interlayer dielectric film IL9. Next, by performing a photolithography process and etching process to the polyimide film PIL, an opening KP1b and an opening KP2b are formed in the polyimide film PIL. The opening KP1 exposing the first electrode pad PEL1 is formed by the opening KP1a and the opening KP1b. The opening KP2 exposing the second electrode pad PEL2a is formed by the opening KP2a and the opening KP2b. Next, as shown in FIG. 10, by performing a polishing process on the back surface of the semiconductor substrate SUB, the thickness of the semiconductor substrate SUB is reduced (back surface polishing step).

Next, for example, an electric test (wafer test) of the semiconductor device is performed. Then, by performing dicing to the semiconductor substrate SUB, it is taken out as the first semiconductor chip SCP1. Next, the first semiconductor chip SCP1 is mounted on the lead frame LFM1 (refer to FIG. 2). The second semiconductor chip SCP2 formed in the same manner as the first semiconductor chip SCP1 is mounted on the lead frame LFM2 (refer to FIG. 2).

Next, the first semiconductor chip SCP1 and the second semiconductor chip SCP2 mounted on the lead frame LFM are arranged in the mold (not shown). The first semiconductor chip SCP1 and the second semiconductor chip SCP2 are sealed by filling the mold resin in the mold. Thereafter, the semiconductor device SDV sealed by the sealing resin REN is taken out from the mold, as shown in FIG. 2. The semiconductor device SDV is completed by applying the desired bending process to the lead terminals LFT protruding from the sealing resin REN.

In the semiconductor device SDV described above, it is possible to prevent an electrical short-circuiting along the dielectric interface. Further, it is possible to reduce the curve of the semiconductor substrate SUB caused by polishing the back surface of the semiconductor substrate SUB. These will be explained in comparison with the semiconductor device according to the comparative example.

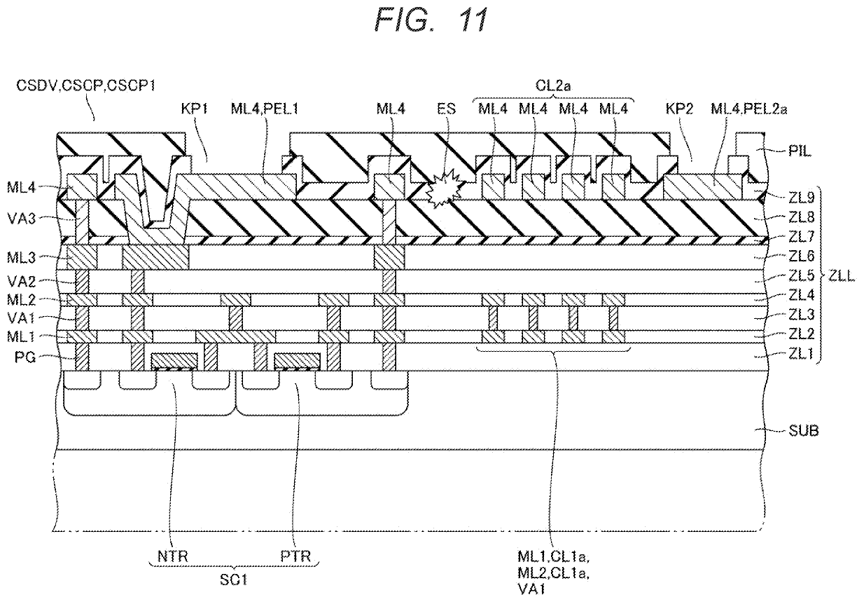

As shown in FIG. 11, in the first semiconductor chip CSP1 of the semiconductor device CSDV according to the comparative example, n-channel transistor NTR and p-channel transistor PTR are formed in a predetermined region in the main surface of the semiconductor substrate SUB. The n-channel transistor NTR and the p-channel transistor PTR constitute a part of the first semiconductor circuit SC1.

An interlayer dielectric film ZL1 is formed over the main surface of the semiconductor substrate SUB so as to cover the n-channel transistor NTR and the p-channel transistor PTR. The contact plugs PG are formed so as to penetrate the interlayer dielectric film ZL1. An interlayer dielectric film ZL2 is formed so as to cover the interlayer dielectric film ZL1. The conductive films ML1 are formed in trenches of the interlayer dielectric film ZL2. The conductive films ML1 include wirings of the first layer and the first inductor CL1a of the first layer.

An interlayer dielectric film ZL3 is formed so as to cover the interlayer dielectric film ZL2. The vias VA1 are formed so as to penetrate the interlayer dielectric film ZL3. An interlayer dielectric film ZL4 is formed so as to cover the interlayer dielectric film ZL3. The conductive films ML2 are formed in trenches of the interlayer dielectric film ZL4. The conductive films ML2 include wirings of the second layer and the first inductor CL1a of the second layer. An interlayer dielectric film ZL5 is formed so as to cover the interlayer dielectric film ZL4.

The vias VA2 are formed so as to penetrate the interlayer dielectric film ZL5. An interlayer dielectric film ZL6 is formed so as to cover the interlayer dielectric film ZL5. Conductive films ML3 are formed in trenches of the interlayer dielectric film ZL6. An interlayer dielectric film ZL7 is formed so as to cover the interlayer dielectric film ZL6. An interlayer dielectric film ZL8 is formed so as to cover the interlayer dielectric film ZL8. The vias VA3 are formed so as to penetrate the interlayer dielectric film ZL7 and the interlayer dielectric film ZL8.

The conductive films ML4 are formed on the surface of the interlayer dielectric film ZL8. The conductive film ML4 include, in addition to wirings of the fourth layer, the first electrode pad PEL1, the second inductor CL2a and the second electrode pad PEL2a. The first electrode pad PEL1 is electrically connected to the conductive film ML3 of the third layer. An interlayer dielectric film ZL9 is formed so as to cover the conductive films ML4. The polyimide film PIL is formed so as to cover the interlayer dielectric film ZL9. The opening KP1 exposing the first electrode pad PEL1 is formed. The opening KP2 exposing the second electrode pad PEL2a is formed.

In the semiconductor device SDV according to the comparative example, among the conductive films ML4 arranged in the fourth layer, a high voltage is applied to the conductive films ML4 constituting the second inductor CL2a and the second electrode pad PEL2a respectively. On the other hand, a low voltage is applied to the conductive films ML4 other than the conductive films ML4 constituting the second inductor CL2a and the second electrode pad PEL2a respectively.

That is, in the first semiconductor chip CSCP1 according to the comparative example, the conductive films ML4 to which low voltage is applied and the conductive films ML4 to which high voltage is applied are formed on the surface of the interlayer dielectric film ZL8. Therefore, between the conductive films ML4 to which the low voltage is applied and the conductive films ML4 to which the high voltage is applied, there is a possibility that an electric short-circuiting ES is caused by a current flowing along the dielectric interface.

Further, there is a need to ensure a breakdown voltage between the first inductor CL1a to which the low voltage is applied and the second inductor CL2a to which the high voltage is applied. Therefore, in the first semiconductor chip CSCP1 according to the comparative example, between the first inductor CL1a and the second inductor CL2a, the interlayer dielectric film ZLL including the interlayer dielectric film ZL8 having a relatively thick film thickness (about several micrometers) is formed.

In the step of manufacturing the first semiconductor chip CSCP1, the interlayer dielectric film ZLL including the interlayer dielectric film ZL8 is formed over the entire surface of the semiconductor substrate SUB. Upon completion of a series of wafer processes for the semiconductor substrate SUB, the semiconductor substrate SUB is then transferred to the assembly process via the back surface polishing process.

In the back surface polishing process, the polishing process is performed to the back surface of the semiconductor substrate SUB, and then the thickness of the semiconductor substrate SUB is thinner than the original thickness (see the two-dot chain line in FIG. 11). Moreover, it is in a state that the interlayer dielectric film ZLL including the interlayer dielectric film ZL8 having a relatively thick film thickness is formed over the entire surface of the semiconductor substrate SUB. The interlayer dielectric film ZL8 or the like having a relatively thick film thickness has a film stress (compressive stress).

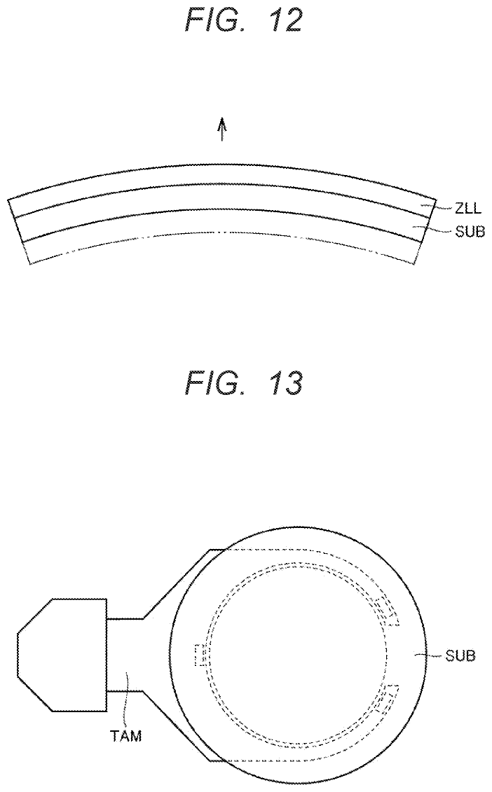

Therefore, by the film stress which the interlayer dielectric film ZLL has, there is a possibility that the curve of the semiconductor substrate SUB which is thinner than the initial thickness is likely to occurs. Specifically, as shown in FIG. 12, by compressive stresses which the interlayer dielectric film ZLL (such as interlayer dielectric film ZL8) has, it is assumed that the semiconductor substrate SUB is curved so as to be convex upward.

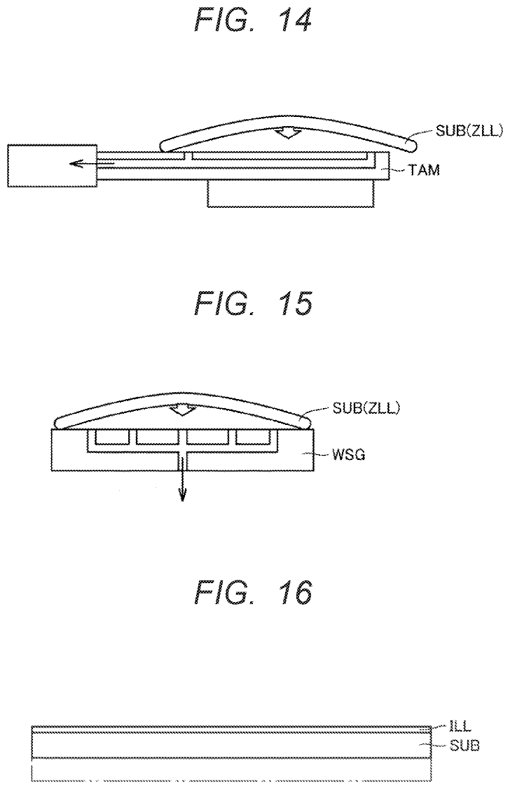

In the process after the back surface polishing process and the assembly process, there is a step of transferring the semiconductor substrate SUB by the transfer arm TAM (refer to FIG. 13, etc.). At this time, as shown in FIG. 13 and FIG. 14, when the semiconductor substrate SUB is curved, it is assumed that the semiconductor substrate SUB is not attached well by the transfer arm TAM, and that transfer errors occur.

Further, in the process after the back surface polishing process and the assembly process, there is a step of performing a desired process to the semiconductor substrate SUB while the semiconductor substrate SUB is placed on the wafer stage WSG (refer to FIG. 15). At this time, as shown in FIG. 15, when the semiconductor substrate SUB is curved, it is assumed that the semiconductor substrate SUB is not successfully attached by the wafer stage WSG and that an attachment error occurs.

In contrast to the semiconductor device CSDV (first semiconductor chip CSCP1) according to the comparative example, the semiconductor device SDV (first semiconductor chip SCP1) according to the first embodiment has the following effects.

First, in the first semiconductor chip SCP1 according to the first embodiment, the conductive films CDL include the conductive films ML1, ML2, ML3 (first conductive film group) to which the low voltage is applied, and the conductive films ML4 (second conductive film group) to which the high voltage is applied. Only the conductive films ML4 are formed on the surface of the interlayer dielectric film IL8 where the conductive films ML4 to which the high voltage is applied is formed.

Of the conductive films ML1, ML2, ML3 to which the low voltage is applied, the conductive films ML3 formed on the uppermost layer is formed on the surface of the interlayer dielectric film IL5. That is, the conductive films ML1, ML2, ML3 to which the low voltage is applied are located below the conductive films ML4 to which the high voltage is applied and are located closer to the main surface (layers) of the semiconductor substrate SUB.

Thus, the current flow along the dielectric interface is suppressed between the conductive films ML3 or the like to which the low voltage is applied and the conductive films ML4 to which the high voltage is applied, it is possible to prevent an electric short-circuiting occurs.

Further, in the first semiconductor chip SCP1, between the first inductor CL1a and the second inductor CL2a, the interlayer dielectric film ILL including the interlayer dielectric film IL8 having a relatively thick film thickness (about several micrometers) is formed. Thus, it is possible to ensure the breakdown voltage between the first inductor CL1a to which the low voltage is applied and the second inductor CL2a to which the high voltage is applied.

Furthermore, the interlayer dielectric film IL8 having a relatively thick film thickness interposed between the first inductor CL1a and the second inductor CL2a is not formed in a region other than the region where the second inductor CL2a is arranged. The interlayer dielectric film IL8 located in a region other than the region where the second inductor CL2a is arranged will be removed after the second inductor CL2a is formed (see FIG. 7).

Therefore, in the interlayer dielectric film ILL, the film stress (compressive stress) of the interlayer dielectric film IL8 having a relatively thick film thickness is reduced. Thus, as shown in FIG. 16, it is suppressed that the semiconductor substrate SUB which is thinner than the initial thickness to curve so as to be convex upward, and it is a flatter state as compared with the comparative example.

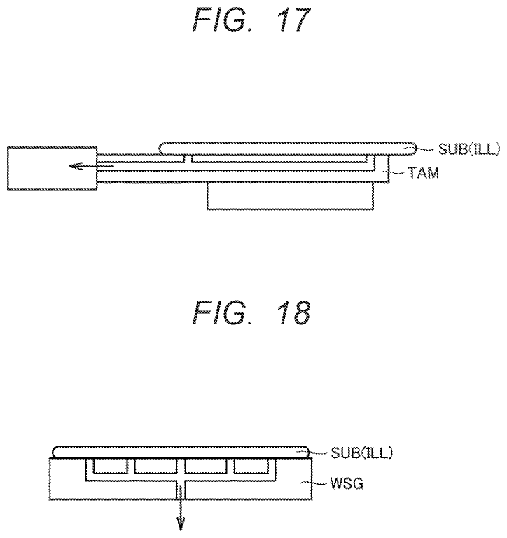

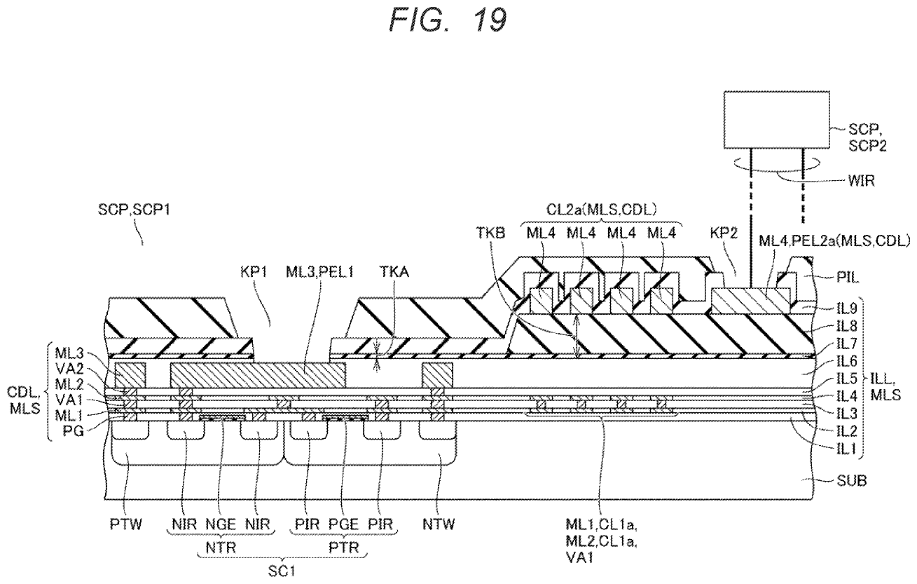

As a result, in the process after the back surface polishing process and the assembling process, as shown in FIG. 17, the semiconductor substrate SUB is attached to the transfer arm TAM well, and the occurrence of transfer errors can be prevented. In addition, as shown in FIG. 18, the semiconductor substrate SUB is successfully attached by the wafer stage WSG, and the occurrence of attachment errors can be prevented.

### Second Embodiment

Here, the film type of the interlayer dielectric film ILL interposed between the first inductor CL1a and the second inductor CL2a will be specified.

As shown in FIG. 19, between the first inductor CL1a and the second inductor CL2a, the interlayer dielectric film ILL including the interlayer dielectric film IL7 (first interlayer dielectric film) and the interlayer dielectric film IL8 (second interlayer dielectric film) is formed. The interlayer dielectric film IL8 has a relatively thick film thickness (about several micrometers). On the other hand, in the region other than the region where the second inductor CL2a is arranged, such as the region where the first electrode pad PEL1 is arranged, although the interlayer dielectric film IL7 is formed, the interlayer dielectric film IL8 is not formed.

That is, the interlayer dielectric film IL7 is formed in a region where the second inductor CL2a is arranged and in a region other than the region where the second inductor CL2a is arranged. Incidentally, in a region other than the region where the second inductor CL2a is arranged, the interlayer dielectric film IL7 may be partially formed, for example, in a region to function as an etching stopper. The interlayer dielectric film IL8 is formed in a region where the second inductor CL2a is arranged, and is not formed in a region other than the region where the second inductor CL2a is arranged.

Therefore, the film thickness TKA of the interlayer dielectric film CL2a located in a region other than the region where the second inductor IL7 is arranged is thinner than the film thickness TKB of the interlayer dielectric film IL7, IL8 interposed between the first inductor CL1a and the second inductor.

In the semiconductor device SDV (first semiconductor chip SCP1) according to the second embodiment, as the film type of the interlayer dielectric film IL7 and interlayer dielectric film IL8, different films with etching characteristics are applied to each other. Here, a silicon nitride film is applied as one example of the interlayer dielectric film IL7. A silicon oxide film is applied as one example of the interlayer dielectric film IL8. Since other configurations are the same as those of the semiconductor device SDV shown in FIG. 3, the same members are denoted by the same reference numerals, and descriptions thereof will not be repeated except when required.

In the semiconductor device SDV described above, in addition to the effects described for the semiconductor device SDV described above, the following effects can be obtained.

That is, in the step of manufacturing the first semiconductor chip SCP1, when removing the interlayer dielectric film IL8 located in a region other than the region where the second inductor CL2a is arranged, it is possible to remove the interlayer dielectric film IL8 by the interlayer dielectric film IL7 as an etching stopper. In this case, it is possible to reliably remove the silicon oxide film (interlayer dielectric film IL8) while leaving the silicon nitride film (interlayer dielectric film IL7).

Thus, for example, as compared with the case where the interlayer dielectric film IL7 and the interlayer dielectric film IL8 are formed by the interlayer dielectric film ILL of one layer, it is possible to accurately control the thickness of the interlayer dielectric film ILL located in a region other than the region where the second inductor CL2a is arranged.

In the semiconductor device SDV (first semiconductor chip SCP1) described above, the case of applying a silicon nitride film as the interlayer dielectric film IL7 and applying a silicon oxide film as the interlayer dielectric film IL8 is described. The film type is not limited to these, and other film types having etching characteristics that differ from each other may be used as long as the interlayer dielectric film IL8 can be removed while leaving the interlayer dielectric film IL7.

### Third Embodiment

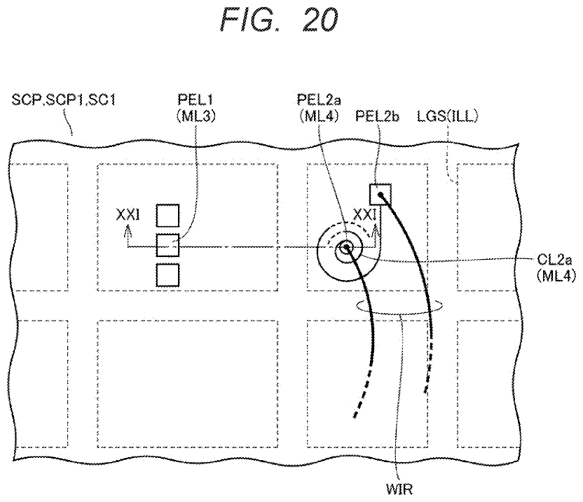

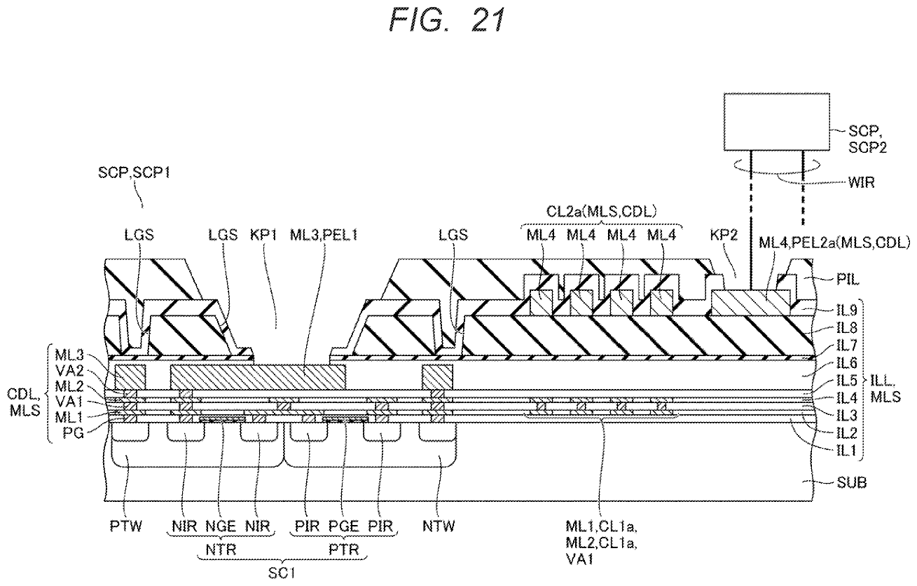

Here, a modified example of the structure to reduce the film stresses of the interlayer dielectric film will be described. As shown in FIGS. 20 and 21, in the first semiconductor chip SCP1 (semiconductor device SDV), trenches LGS are formed in the interlayer dielectric film IL8 located in a region other than the region where the second inductor CL2a is arranged. The trenches LGS are formed in a lattice pattern, for example. Since other configurations are the same as those of the semiconductor device SDV shown in FIG. 3, the same members are denoted by the same reference numerals, and descriptions thereof will not be repeated except when required.

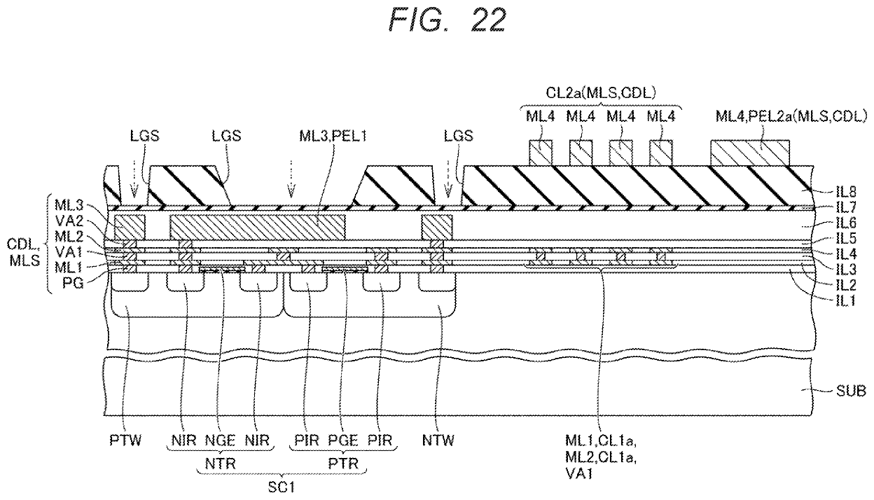

Next, one example of a method of manufacturing the first semiconductor chip SCP1 (semiconductor device SDV) described above is explained. After undergoing the same steps as those shown in FIGS. 4 to 6, the trenches LGS are formed by performing a photolithography process and etching process on the interlayer dielectric film IL8 as shown in FIG. 22. The trenches LGS are formed so as to reach the interlayer dielectric film IL7 through the interlayer dielectric film IL8. The trenches LGS, with the semiconductor substrate SUB in plan view, for example, are formed in a lattice pattern.

As described above, as the interlayer dielectric film IL7 and the interlayer dielectric film IL8, by applying film types which etching characteristics are different from each other, it is possible to etch the interlayer dielectric film IL8 while leaving the interlayer dielectric film IL7.

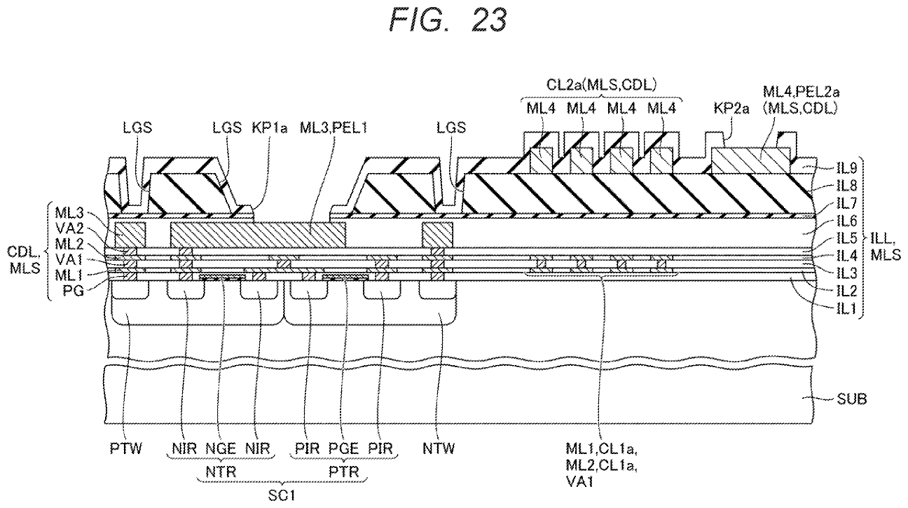

Next, similarly to the process shown in FIG. 8, as shown in FIG. 23, the interlayer dielectric film IL9 is formed so as to cover the second inductor CL2a and the interlayer dielectric film IL7 or the like. The opening KP1a exposing the first electrode pad PEL1 is formed. The opening KP2a exposing the second electrode pad PEL2a is formed.

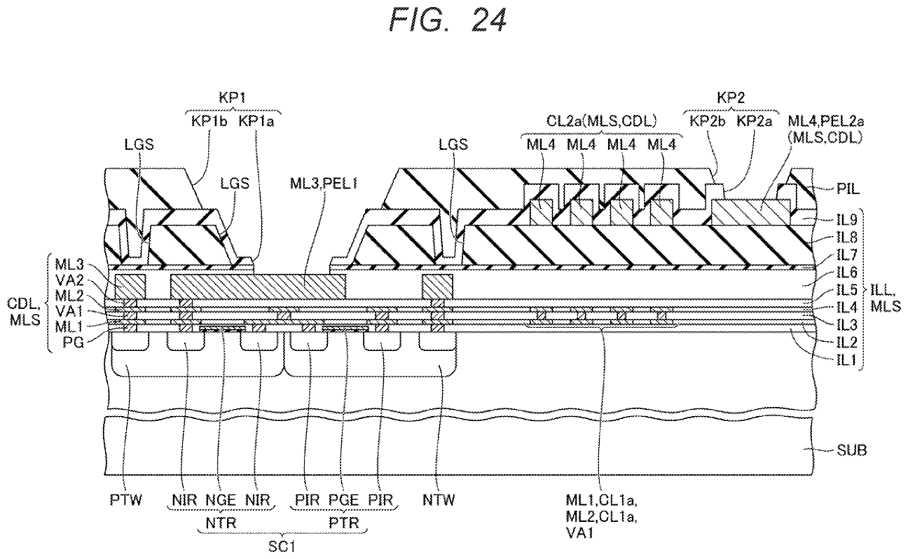

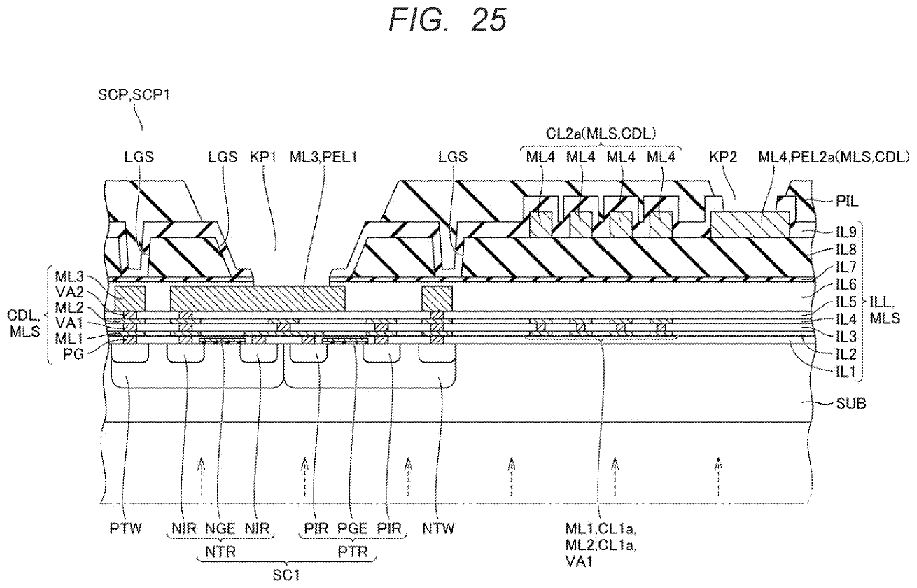

Next, similarly to the process shown in FIG. 9, as shown in FIG. 24, the polyimide film PIL is formed so as to cover the interlayer dielectric film IL9. The opening KP1b and the opening KP2b are formed. Next, as in the process shown in FIG. 10, as shown in FIG. 25, by performing a polishing process on the back surface of the semiconductor substrate SUB, the thickness of the semiconductor substrate SUB is reduced (back surface polishing process). Thereafter, the assembly process is performed to complete the semiconductor device SDV (see, for example, FIG. 2).

In the first semiconductor chip SCP1 (semiconductor device SDV) described above, the trenches LGS are formed in a lattice pattern in the interlayer dielectric film IL8 located in a region other than the region where the second inductor CL2a is arranged. Thus, in the interlayer dielectric film ILL, the film stress of the interlayer dielectric film IL8 having a relatively thick film thickness (compressive stress) is reduced, and it is possible to suppress the semiconductor substrate SUB which is thinner than the initial thickness to curve so as to be convex upward.

Consequently, as described in the first embodiment, for example, a transfer error of the semiconductor substrate SUB by the transfer arm can be prevented. Further, it is possible to prevent the attachment error of the semiconductor substrate SUB in the wafer stage.

In the semiconductor device SDV described above, the first semiconductor chip SCP1 in which the first inductor CL1a to which the low voltage is applied is arranged on the lower side (side close to the main surface) and the second inductor CL2a to which the high voltage is applied is arranged on the upper side, has been described as one example. In the second semiconductor chip SCP2, the high-low relation of the voltage is reversed, the inductor to which the high voltage is applied is arranged on the lower side, and the inductor to which the low voltage is applied is arranged on the upper side (not shown). It can also be applied to such a structure.

The semiconductor device described in the respective embodiments can be variously combined as required.

Although the invention made by the present inventor has been specifically described based on the embodiment, the present invention is not limited to the embodiment described above, and it is needless to say that various modifications can be made without departing from the gist thereof.

What is claimed is:

1. A semiconductor device comprising:
a first semiconductor chip in which a first semiconductor circuit, a first inductor and a second inductor are formed,
wherein the first semiconductor chip includes:
a semiconductor substrate having a main surface; and
a multilayer wiring structure in which a plurality of conductive films and a plurality of interlayer dielectric films are laminated, the multilayer wiring structure being formed so as to cover the main surface of the semiconductor substrate,
wherein the plurality of conductive films in the multilayer wiring structure includes:
a first conductive film group including the first inductor to which a first voltage is applied, the first conductive film group constituting the first semiconductor circuit; and
a second conductive film group including the second inductor to which a second voltage different from the first voltage is applied,
wherein the first conductive film group is arranged in a layer closer to the main surface and below a layer in which the second conductive film group is arranged,
wherein, when i and j are defined as natural numbers representing an order of layers laminated sequentially from the main surface of the semiconductor substrate in the plurality of conductive films, the first inductor is arranged in an i-th layer, and the second inductor is arranged in a j-th layer, and
wherein between the i-th layer and the j-th layer, at least one layer of the plurality of conductive films is arranged.

2. The semiconductor device according to claim 1,
wherein, when k is defined as a natural number representing the order of layers laminated sequentially from the main surface of the semiconductor substrate in the plurality of conductive films, the first conductive film group includes a first electrode pad arranged in a k-th layer, and
wherein the k-th layer is located below the j-th layer, and is either the i-th layer or a layer over the i-th layer.

3. The semiconductor device according to claim 2,
wherein, in one interlayer dielectric film of the plurality of interlayer dielectric films located between the k-th layer and the j-th layer, a film thickness of the interlayer dielectric film located in a region other than a region where the second inductor is arranged is thinner than a film thickness of the interlayer dielectric film located in the region where the second inductor is arranged.

4. The semiconductor device according to claim 3,
wherein the one interlayer dielectric film located between the k-th layer and the j-th layer includes:
a first interlayer dielectric film; and
a second interlayer dielectric film formed so as to cover the first interlayer dielectric film,
wherein the first interlayer dielectric film is formed in the region other than the region where the second inductor is arranged and in the region where the second inductor is arranged, and
wherein the second interlayer dielectric film is formed in the region where the second inductor is arranged while the second interlayer dielectric film is not formed in the region other than the region where the second inductor is arranged.

5. The semiconductor device according to claim 3,
wherein, in the one interlayer dielectric film located between the k-th layer and the j-th layer, a latticed trench is formed in the interlayer dielectric film located in the region other than the region where the second inductor is arranged.

6. The semiconductor device according to claim 5,
wherein the one interlayer dielectric film located between the k-th layer and the j-th layer includes:
a first interlayer dielectric film; and
a second interlayer dielectric film formed so as to cover the first interlayer dielectric film,
wherein the first interlayer dielectric film is formed in the region other than the region where the second inductor is arranged and in the region where the second inductor is arranged, and
wherein the latticed trench is formed in the second interlayer dielectric film.

7. The semiconductor device according to claim 4,
wherein the first interlayer dielectric film includes a silicon nitride film, and
wherein the second interlayer dielectric film includes a silicon oxide film.

8. The semiconductor device according to claim 1,
wherein the second conductive film group includes a second electrode pad formed in the j-th layer and electrically connected to the second inductor.

9. The semiconductor device according to claim 8, comprising:
a second semiconductor chip to which the second voltage is applied, the second semiconductor chip being arranged at a distance from the first semiconductor chip,
wherein the second semiconductor chip is electrically connected to the second inductor via the second electrode pad.

10. A method of manufacturing a semiconductor device, comprising:
forming a first semiconductor chip including a first inductor, a second inductor and a semiconductor circuit having a semiconductor element,
wherein the forming the first semiconductor chip includes:
preparing a semiconductor substrate having a main surface;
forming the semiconductor element in the main surface of the semiconductor substrate; and
forming a multilayer wiring structure by laminating a plurality of conductive films constituting the semiconductor circuit and electrically connected to the semiconductor element, and a plurality of interlayer dielectric films so as to cover the main surface of the semiconductor substrate,
wherein the forming the multilayer wiring structure includes:
forming a first conductive film group including the first inductor to which a first voltage is applied, the first conductive film group constituting the semiconductor circuit;
forming one of the plurality of interlayer dielectric films so as to cover the first conductive film group; and
forming a second conductive film group including the second inductor to which a second voltage different from the first voltage is applied, so as to cover the one of the plurality of interlayer dielectric films,
wherein, when i and j are defined as natural numbers representing an order of layers laminated sequentially from the main surface of the semiconductor substrate in the plurality of conductive films, the forming the first conductive film group includes forming the first inductor in an i-th layer, and the forming the second conductive film group includes forming the second inductor in a j-th layer, and
wherein the forming the multilayer wiring structure includes forming at least one layer of the plurality of conductive films between the i-th layer and the j-th layer.

11. The method according to claim 10,
wherein, when k is defined as a natural number representing the order of layers laminated sequentially from the main surface of the semiconductor substrate in the plurality of conductive films, the forming the first conductive film group includes forming a first electrode pad in a k-th layer which is located below the j-th layer and is either the i-th layer or a layer over the i-th layer.

12. The method according to claim 11, comprising:
forming one interlayer dielectric film of the plurality of interlayer dielectric films between the first electrode pad and the second inductor,
wherein the forming the multilayer wiring structure includes thinning a film thickness of the one interlayer dielectric film located in a region other than a region where the second inductor is arranged than a film thickness of the one interlayer dielectric film located in the region where the second inductor is arranged, and
wherein, after the forming the multilayer wiring structure, the method comprises:
performing a polishing process to a back surface opposite to the main surface of the semiconductor substrate; and
performing a desired treatment to the semiconductor substrate after transferring the semiconductor substrate of which the polishing process is performed to the back surface.

13. The method according to claim 12,
wherein the forming the one interlayer dielectric film of the plurality of interlayer dielectric films between the first electrode pad and the second inductor includes:
forming a first interlayer dielectric film so as to cover the first electrode pad; and
forming a second interlayer dielectric film of which etching characteristics is different from etching characteristics of the first interlayer dielectric film so as to cover the first interlayer dielectric film, the second interlayer dielectric film being thicker than the first interlayer dielectric film; and
removing the second interlayer dielectric film located in the region other than the region where the second inductor is arranged.

14. The method according to claim 13,
wherein, in the removing the second interlayer dielectric film, the second interlayer dielectric film is removed in the region other than the region where the second inductor is arranged.

15. The method according to claim 13,
wherein, in the removing the second interlayer dielectric film, the second interlayer dielectric film is removed in a lattice pattern in the region other than the region where the second inductor is arranged.

16. The method according to claim 13,
wherein a silicon nitride film is formed in the forming the first interlayer dielectric film, and
wherein a silicon oxide film is formed in the forming the second interlayer dielectric film.
